(19) United States
(12) Patent Application Publication
(10) Pub. No.: US 2009/0102491 A1
(43) Pub. Date: Apr. 23, 2009

(54) MULTIPORT TEST-SET FOR SWITCH MODULE IN NETWORK ANALYZER

(76) Inventor: Masaki Bessho, Hyogo (JP)

Correspondence Address: Agilent technologies;Legal Department DL 429, Intellectual Property Administration, P O Box 7599, Loveland, CO, 80537-0599, US

(21) Appl. No.: 11/990,671

(22) PCT Filed: Jul. 20, 2006
(86) PCT No.: PCT/US2006/028109

§ 371 Date: Feb. 19, 2008

(30) Foreign Application Priority Data
Aug. 18, 2005 (JP) 2005-237507

(51) Int. Cl. G01R 27/32

(52) U.S. Cl. 324/629

(57) ABSTRACT

A system for measuring a multiport device connected to a network analyzer via a test-set comprising a multiport network analyzer; a test-set having multiple real switches wherein at least one set of real switches is capable of being connected together as needed between selection terminals; and a device for controlling the network analyzer and the test-set, wherein two or more predetermined real switches that have been connected together, including at least one real switch with an open terminal, are regarded as one imaginary switch, and the control device controls the selection status of the real switches related to the imaginary switch based on the combination of terminals to which electricity is to be conducted as instructed by the user for this imaginary switch.

### 1. FIELD OF THE INVENTION

The present invention pertains to the measurement of a multiport device, and in particular, relates to network measurement of a switch module for mobile telephones.

### 2. DISCUSSION OF THE BACKGROUND ART

Newer mobile telephone terminals comprise multiple devices conforming to different radio transmission regulations, and further comprise a switch module for using one antenna with all of these devices. The switch module is referred to as an SWM hereafter. The SWM has many ports for connecting multiple devices as well as an antenna. For instance, SWMs for a triple band (GSM, DCS, PCS) have nine ports at the most. The current one-box multiport network analyzer having a maximum of four measurement ports is combined with a test-set for measuring a device under test having more ports than there are measurement ports. A test-set wherein any of the measurement ports of a network analyzer are electrically connected to a port that will be connected to a device under test will require a huge number of switches and is expensive. Therefore, an inexpensive test-set is provided whereby the number of necessary switches is reduced by limiting the device under test to an SWM (for instance, refer to JP Unexamined Patent Application (Kokai) 2002-152,150). It should be noted that a port is the same as a terminal here.

The newest SWMs for 4-band GSM and 2-band UMTS, and have a maximum of 13 ports. Special test-sets for SWMs are optimized for the individual SWM and the existing test-sets for SWMs have a limited number of ports and cannot measure the newest SWMs. Moreover, it is necessary to simultaneously measure the SWM and the filter bank that is used in combination with the SWM. A filter bank has multiple filters in one device. There are cases in which this filter bank is housed inside the SWM. In this case, it is provided as one individual chip. As with the filter bank, the chip unit must also be measured. The filter bank for an SWM corresponding to the above-mentioned 6 bands has 4 filters and 16 ports at most. Filter banks have an internal structure that is different from an SWM and the requirements for the test-set therefore are different from those of the SWM. Consequently, a conventional test-set cannot measure both the SWM and the filter bank.

### SUMMARY OF THE INVENTION

The first subject of the invention is a test-set for connecting a device under test having more terminals than the number of measurement ports in a network analyzer to this network analyzer, characterized in that it comprises multiple one-pole, multi-throw switches that will be electrically connected to these measurement ports and at least one switch capable of being connected as needed to a selection terminal of this one-pole, multi-throw switch.

Moreover, the second subject of the invention is characterized in that by means of the test-set in the first subject of the invention, the network analyzer is a four-port network analyzer and comprises four one-pole, four-throw switches and three one-pole, two-throw switches, and a selection terminal of these one-pole two-throw switches is capable of being connected as needed to a selection terminal of these one-pole four-throw switches.

The third subject of the invention is characterized in that it is a system for measuring a multiport device connected to a network analyzer via a test-set comprising a multiport network analyzer; a test-set having multiple real switches wherein at least one set of real switches is capable of being connected together as needed between selection terminals; and a device for controlling the network analyzer and the test-set, this system being characterized in that two or more real switches that have been connected together with predetermined connection, including at least one real switch which selection terminals are opened, are regarded as one imaginary switch, and this control device controls the selection status of these real switches related to this imaginary switch based on the combination of terminals to which electricity is to be conducted as instructed by the user for this imaginary switch.

The test-set of the present invention further comprises a switch capable of being connected as needed to a one-pole, four-throw switch connected to a network analyzer. The SWM and the filter bank can be connected to the network analyzer in the form needed for measurement. Moreover, by means of the measurement system of the present invention, all related real switches can be controlled by regarding multiple real switches connected together as one imaginary switch and specifying only the terminal of the imaginary switch; as a result, the test-set is guaranteed to be as useful as an SWM-specialty test-set and any mis-setting of the test-set by the user can be prevented.

### BRIEF DESCRIPTION OF THE DRAWINGS

FIG. 1 is a front view of measurement system 10.

FIG. 2 is a block diagram showing the structure of measurement system 10.

FIG. 3 is a block diagram showing the internal structure of switch array 400.

FIG. 4 is a drawing showing the detailed structure of switch 410.

FIG. 5 is a block diagram showing the internal structure of SWM 500.

FIG. 6 is a block diagram showing measurement system 10 to which SWM 500 has been connected.

FIG. 7 is a drawing showing test-set 200 wherein a predetermined connection has been made between terminals.

FIG. 8 is a block diagram showing the internal structure of filter bank 600.

FIG. 9 is a block diagram showing the measurement system 10 to which filter bank 600 has been connected.

### DETAILED DESCRIPTION OF THE PREFERRED EMBODIMENT

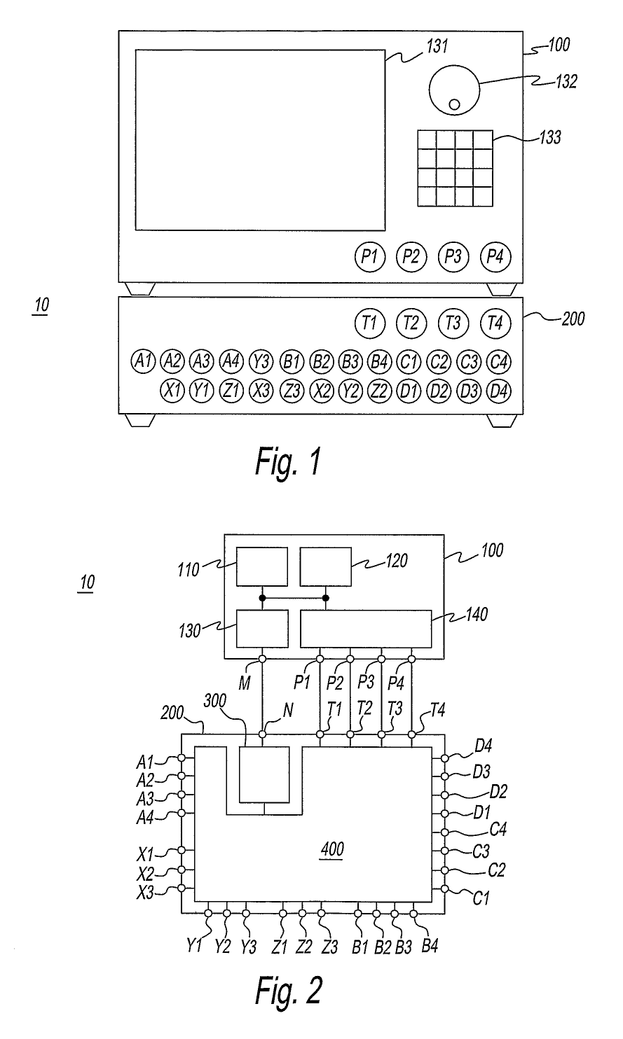

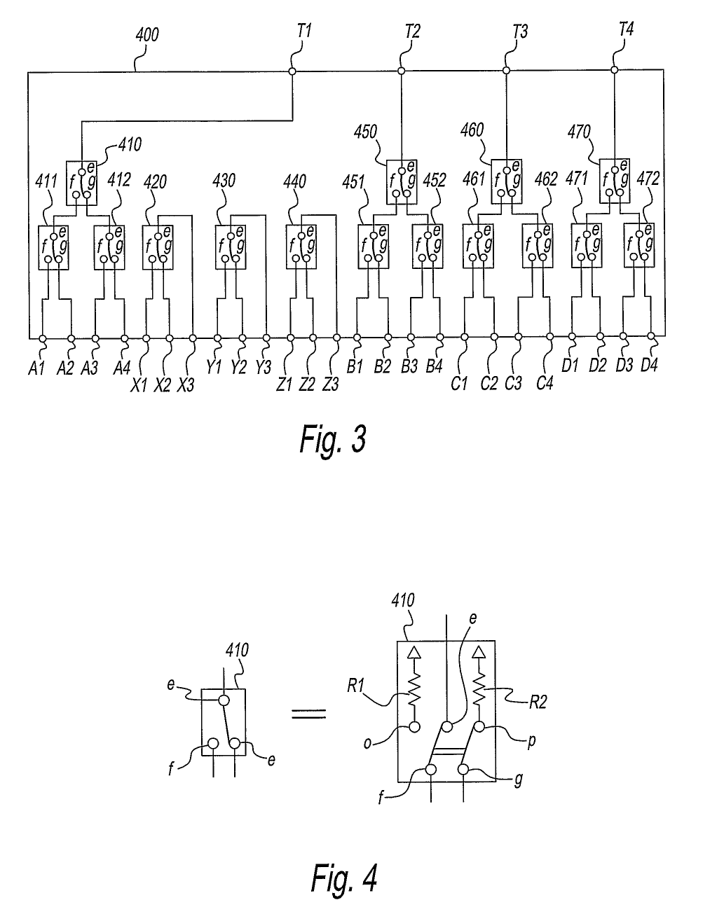

Next, the present invention will be described based on preferred embodiments shown in the attached drawings. The embodiments of the present invention are measurement systems that use multiport test sets. Refer to FIGS. 1, 2, and 3. FIG. 1 is a front view showing a measurement system 10 of an embodiment of the present invention. FIG. 2 is a block diagram showing the structure of measurement system 10. FIG. 3 is a block diagram showing the internal structure of a switch array 400 in FIG. 2. The structure of measurement system 10 will be described first. Measurement system 10 comprises a multiport network analyzer 100 with 4 ports, and a multiport test-set 200.

Network analyzer 100 comprises a control part 110, a memory part 120, an interface part 130, and a measuring part 140. Control part 110 is the device that controls memory part 120, interface part 130, and measuring part 140 and performs data exchange by communicating with memory part 120, interface part 130, and measuring part 140. Control part 110 comprises, for instance, a CPU or a DSP, an ASIC or an FPGA, and the like. Memory part 120 is the device that stores data and programs. Memory part 120 comprises, for instance, a DRAM or a ROM, or a hard-disk drive or a removable-disk drive. Interface part 130 is the device for outside communication by network analyzer 100. Interface part 130 comprises, for instance, a display 131 and a vernier 132, a keypad 133, and similar elements. Moreover, interface part 130 has a control terminal M for transmitting and receiving signals for controlling test-set 200. Measuring part 140 is the device for measuring the network characteristics of the element or circuit that is the device under test. Measuring part 140 comprises a measuring port P1, a measuring port P2, a measuring port P3, and a measuring port P4. The device under test is connected via test-set 200 to measuring port P1, measuring port P2, measuring port P3, and measuring port P4.

Test-set 200 comprises a control part 300 and switch array 400. Control part 300 is a device for controlling switch array 400. Control part 300 comprises a control terminal N and is electrically connected to network analyzer 100 via control terminal N. Control part 300 receives commands for controlling switch array 400 from network analyzer 100. Switch array 400 comprises terminals T1, T2, T3, and T4 for connection to the measurement ports of network analyzer 100. Moreover, switch array 400 comprises terminals A1, A2, A3, A4, B1, B2, B3, B4, C1, C2, C3, C4, D1, D2, D3, D4, X1, X2, X3, Y1, Y2, Y3, Z1, Z2, and Z3 for connecting a device under test. These switches are schematically represented as SPDT (single-pole, double-throw) in FIG. 3, but they actually have the structure shown in FIG. 4.

Refer to FIG. 4. FIG. 4 shows the internal structure of a switch 410 as a typical example of an SPDT switch of switch array 400. The left side of FIG. 4 is an outline of the internal structure of switch 410, and the right side is a detailed drawing of the internal structure of switch 410. Electricity flows between terminals e and f when switch 410 selects terminal f. Moreover, electricity flows between terminals e and g when switch 410 selects terminal g. Switch 410 comprises resistors R1 and R2 for termination. When switch 410 selects terminal g, terminal f is terminated by resistor R1. It should be noted that the triangles at one end of resistors R1 and R2 in FIG. 4 represent ground. The terminal on the polar side of a one-pole, multi-throw switch is called the common terminal and the other terminal is called the selection terminal. For instance, terminal f and terminal g are the selection terminals of switch 410. Switches 411, 412, 420, 430, 440, 450, 451, 452, 460, 461, 462, 470, 471, and 472 have the same structure as switch 410 shown on the right in FIG. 4, and each of these switches comprise terminal e, terminal f, terminal g, resistor R1 and resistor R2.

Refer to FIG. 3. Terminal e of switch 410 is electrically connected to terminal T1; terminal f of switch 410 is electrically connected to terminal e of switch 411; and terminal g of switch 410 is electrically connected to terminal e of switch 412. Switch 410, switch 411, and switch 412 constitute an SP4T (single-pole, four-throw; single pole 4-position; or SP4P) switch through these connections. Terminal f of switch 411 is electrically connected to terminal A1, and terminal g of switch 411 is electrically connected to terminal A2. Terminal f of switch 412 is electrically connected to terminal A3 and terminal g of switch 412 is electrically connected to terminal A4.

Terminal e of switch 420 is electrically connected to terminal X3; terminal f of switch 420 is electrically connected to terminal X1; and terminal g of switch 420 is electrically connected to terminal X2.

Terminal e of switch 430 is electrically connected to terminal Y3; terminal f of switch 430 is electrically connected to terminal Y1; and terminal g of switch 430 is electrically connected to terminal Y2.

Terminal e of switch 440 is electrically connected to terminal Z3; terminal f of switch 440 is electrically connected to terminal Z1; and terminal g of switch 440 is electrically connected to terminal Z2.

Terminal e of switch 450 is electrically connected to terminal T2; terminal f of switch 450 is electrically connected to terminal e of switch 451; and terminal g of switch 450 is electrically connected to terminal e of switch 452 Switch 450, switch 451, and switch 452 form an SP4T (single-pole, four-throw) switch by these connections. Terminal f of switch 451 is electrically connected to terminal B1 and terminal g of switch 451 is electrically connected to terminal B2. Terminal f of switch 452 is electrically connected to terminal B3 and terminal g of switch 452 is electrically connected to terminal B4.

Terminal e of switch 460 is electrically connected to terminal T3; terminal f of switch 460 is electrically connected to terminal e of switch 461; and terminal g of switch 460 is electrically connected to terminal e of switch 462. Switch 460, switch 461, and switch 462 form an SP4T (single-pole, 4-throw) switch by these connections. Terminal f of switch 461 is electrically connected to terminal C1 and terminal g of switch 461 is electrically connected to terminal C2. Terminal f of switch 462 is electrically connected to terminal C3 and terminal g of switch 462 is electrically connected to terminal C4.

Terminal e of switch 470 is electrically connected to terminal T4; terminal f of switch 470 is electrically connected to terminal e of switch 471; and terminal g of switch 470 is electrically connected to terminal e of switch 472. Switch 470, switch 471, and switch 472 form an SP4T (single-pole, four-throw) switch by these connections. Terminal f of switch 471 is electrically connected to terminal D1 and terminal g of switch 471 is electrically connected to terminal D2. Terminal f of switch 472 is electrically connected to terminal D3 and terminal g of switch 472 is electrically connected to terminal D4.

The selection status (conducting status) of switches 410, 411, 412, 420, 430, 440, 450, 451, 452, 460, 461, 462, 470, 471, and 472 is controlled by control part 300.

Refer to FIGS. 1 and 2 as well as FIG. 3. Measurement port P1 and terminal T1, measurement port P2 and terminal T2, measurement port P3 and terminal T3, measurement port P4 and terminal T4, and control terminal M and control terminal N in FIG. 1 are each electrically connected as in FIG. 2.

Next, the user's control of switch 410 of test-set 300, etc. will now be described. Network analyzer 100 has an environment for user programming. The user is capable of listing script commands provided in the programming environment and assigning parameters to the listed commands as necessary. The script commands can be input through interface part 130. The commands listed by the user are stored in memory part 120 as a program. Control part 110 executes the program stored in memory part 120 and controls switch 410, etc. via control part 300 in accordance with the user intentions reflected by the program.

The script commands for controlling switch 410, etc. are PORT1, PORT2, PORT3, PORT4, PORT5, PORT6, and PORT7. PORT1, PORT2, PORT3, and PORT4 correspond to terminals T1 through T4, respectively. Moreover, PORT5 corresponds to terminal X3, PORT6 corresponds to terminal Y3, and PORT7 corresponds to terminal Z3. When a terminal to be opened is designated using successive PORT1 through PORT 7, the related switch is controlled For instance, when the user wants terminal T1 to conduct electricity to terminal A4, he enters “PORT1 A4.” When this script command is executed, switch 410 selects terminal g and switch 412 selects terminal g. Similarly, when the user wants terminal T3 to conduct electricity to terminal C2, he enters “PORT 3 C2.” When this script command is executed, switch 460 selects terminal f and switch 461 selects terminal g. When the user wants terminal Y3 to conduct electricity to terminal Y1, he cites “PORT6 Y1.” When this script command is executed, switch 430 selects terminal f. Thus, it is possible to control the selection status of each switch by designating the combination of terminals that should be opened using script commands. It should be noted that the following parameters (connection terminal name) can each be designated a command when each switch is directly controlled by designating commands.

PORT 1: Either A1, A2, A3, or A4

PORT 2: Either B1, B2, B3, or B4

PORT 3: Either C1, C2, C3, or C4

PORT 4: Either D1, D2, D3, or D4

PORT 5: Either X1 or X2

PORT 6: Either Y1 or Y2

PORT 7: Either Z1 or Z2

Measurement system 10 constructed as described above is ideal for measuring many types of multiport devices. An example will now be explained wherein a 13-port SWM and a 16-port filter bank are measured using measurement system 10.

### WORKING EXAMPLE 1

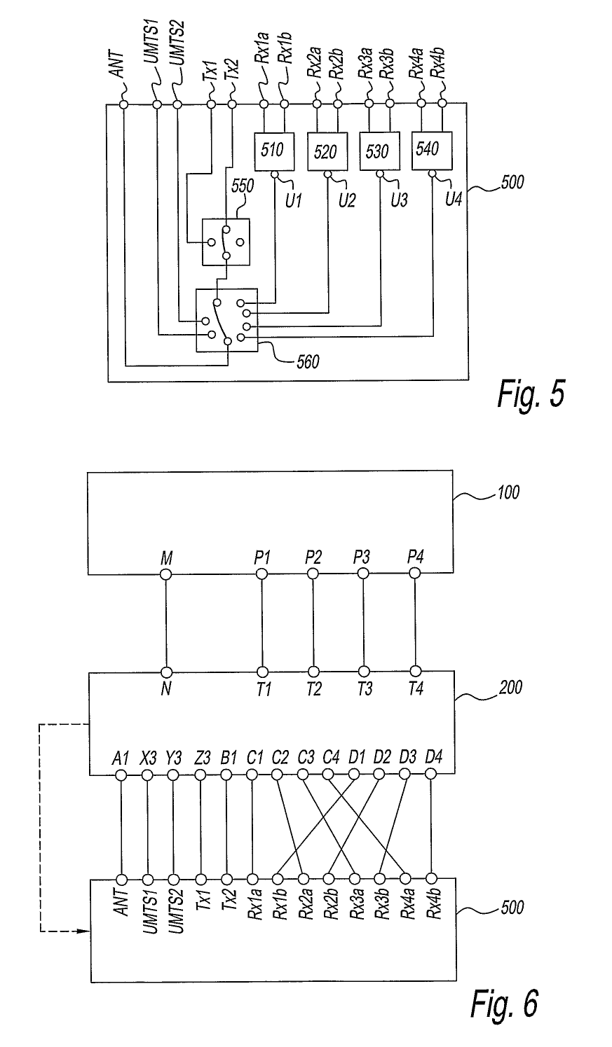

The first working example of the present invention is an example of the measurement of a 13-port SWM. This 13-port SWM is a switch for using 4 transmission systems and 4 reception systems with one antenna and is called an SP8T (single-pole, eight-throw) switch. Refer to FIG. 5 as a block diagram showing the internal structure of a 13-port SWM, which is the device under test. An SWM 500 in FIG. 5 comprises balanced-unbalanced filters 510, 520, 530, and 540, and SP3T (single-pole, three-throw) switch 550; and an SP7T (single-pole, 7-throw) switch 560. Moreover, SWM 500 comprises a terminal ANT for connecting an antenna; terminals UMTS1 and UMTS2 for connecting a UMTS device; terminals Tx1 and Tx2 for connecting the transmitter; and terminals Rx1a, Rx1b, Rx2a, Rx2b, Rx3a, Rx3b, Rx4a, and Rx4b for connecting the receiver. Terminals Tx1 and Tx2 are individually connected to switch 550. One of terminals Tx1 and Tx2 selectively conducts electricity to switch 560 using switch 550. The status of switch 550 can also be such that neither terminal Tx1 nor terminal Tx2 is selected. Terminal Rx1a and Rx1b form the balanced terminal pair of filter 510. The unbalanced terminal U1 of filter 510 is connected to switch 560. Terminals Rx2a and Rx2b form the balanced terminal pair of filter 520. Unbalanced terminal U2 of filter 520 is connected to switch 560. Terminals Rx3a and Rx3b form the balanced terminal pair of filter 530. Unbalanced terminal U3 of filter 530 is connected to switch 560. Terminals Rx4a and Rx4b form the balanced terminal pair of filter 540. Unbalanced terminal U4 of filter 540 is connected to switch 560. Terminal ANT, terminal UMTS1, terminal UMTS2, filter 510, filter 520, filter 530, filter 540, and switch 550 are individually connected to switch 560. Switch 560 selects one of the following: terminal UMTS1, terminal UMTS2, filter 510, filter 520, filter 530, filter 540, and switch 550, and the selection terminal conducts electricity with terminal ANT.

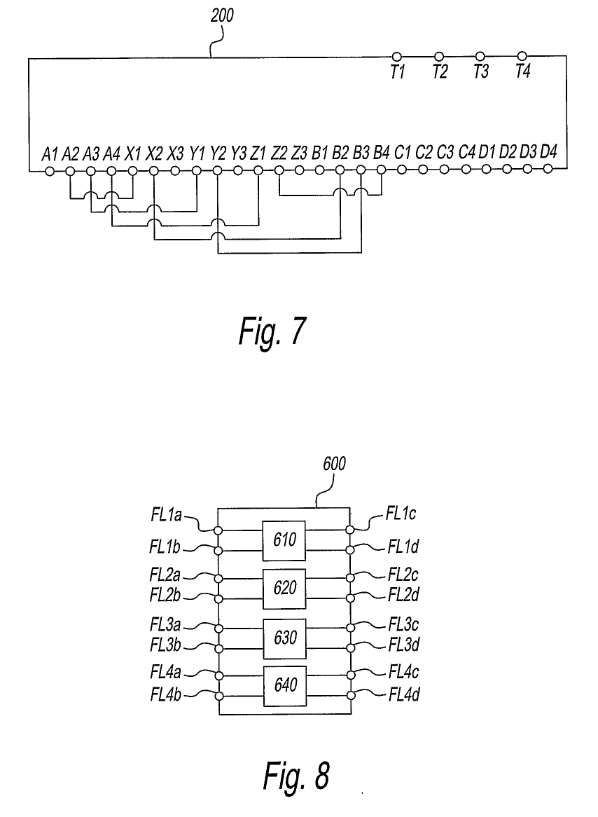

Next, refer to FIGS. 6 and 7. FIG. 6 is a drawing showing network analyzer 100, test-set 200, and the connection of SWM 500. Moreover, FIG. 7 shows the connection between the terminals in test-set 200. The connection between network analyzer 100 and test-set 200 is the same as in FIG. 2 and a detailed description is therefore omitted. As shown in FIG. 6, terminal A1 is connected to terminal ANT, terminal X3 is connected to terminal UMTS1; terminal Y3 is connected to terminal UMTS2; terminal Z3 is connected to terminal Tx1; terminal B1 is connected to terminal Tx2, terminal C1 is connected to terminal Rx1a; terminal C2 is connected to terminal Rx2a; terminal C3 is connected to terminal Rx3a; terminal C4 is connected to terminal Rx4a; terminal D1 is connected to terminal Rx1b; terminal D2 is connected to terminal Rx2b; terminal D3 is connected to terminal Rx3b; and terminal D4 is connected to terminal Rx4b. Moreover, as shown in FIG. 7, terminal X1 is connected to terminal A2; terminal X2 is connected to terminal B2; terminal Y1 is connected to terminal A3; terminal Y2 is connected to terminal B3; terminal Z1 is connected to terminal A4; and terminal Z2 is connected to terminal B4.

Refer to Table 1 as the measurement of each parameter of SWM 500 is described. Table 1 is a table that shows the setting of SWM 500 and the setting of test-set 200 for measuring each parameter of SWM 500. Moving left to right from the furthest left column in the table are the following: the column showing the mode of SWM 500 (Mode), the column showing the selection status of switch 550 (550), the column showing the selection status of switch 560 (560), the column showing the path of measurement of SWM 500 (measurement path), the column showing the internal connection destination of terminal T1 in test-set 200, the column showing the internal connection destination of terminal T2 (T2), the column showing the internal connection destination of terminal T3 (T3), and the column showing the internal connection destination of terminal T4 (T4).

TABLE 1

| SWM | | | | Test-set | | | |
|---|---|---|---|---|---|---|---|
| Mode | 550 | 560 | Measurement course | T1 | T2 | T3 | T4 |
| AMPS/GSM | T × 1 | 550 | T × 1->ANT | A1 | Z3 | * | * |
| TX | | | T × 1->R × 1 | * | Z3 | C1 | D1 |
| | | | T × 1->R × 2 | * | Z3 | C2 | D2 |
| | | | T × 1->R × 3 | * | Z3 | C3 | D3 |
| | | | T × 1->R × 4 | * | Z3 | C4 | D4 |
| | | | T × 1->T × 2 | Z3 | B1 | * | * |
| | | | T × 1->UMTS1 | Z3 | X3 | * | * |
| | | | T × 1->UMTS2 | Z3 | Y3 | * | * |
| DCS/PCS TX | T × 2 | 550 | T × 2->ANT | A1 | B1 | * | * |
| | | | T × 2->R × 1 | * | B1 | C1 | D1 |
| | | | T × 2->R × 2 | * | B1 | C2 | D2 |
| | | | T × 2->R × 3 | * | B1 | C3 | D3 |
| | | | T × 2->R × 4 | * | B1 | C4 | D4 |
| | | | T × 2->T × 1 | Z3 | B1 | * | * |
| | | | T × 2->UMTS1 | X3 | B1 | * | * |
| | | | T × 2->UMTS2 | Y3 | B1 | * | * |
| UMTS800 | * | UMTS1 | UMTS1->ANT | A1 | X3 | * | * |
| | | | UMTS1->R × 1 | * | X3 | C1 | D1 |
| | | | UMTS1->R × 2 | * | X3 | C2 | D2 |
| | | | UMTS1->R × 3 | * | X3 | C3 | D3 |
| | | | UMTS1->R × 4 | * | X3 | C4 | D4 |
| | | | UMTS1->T × 1 | X3 | Z3 | * | * |
| | | | UMTS1->T × 2 | X3 | B1 | * | * |
| | | | UMTS1->UMTS2 | X3 | Y3 | * | * |
| UMTS1900/ | * | UMTS2 | UMTS2 | A1 | Y3 | * | * |
| 2100 | | | UMTS2->R × 1 | * | Y3 | C1 | D1 |
| | | | UMTS2->R × 2 | * | Y3 | C2 | D2 |
| | | | UMTS2->R × 3 | * | Y3 | C3 | D3 |
| | | | UMTS2->R × 4 | * | Y3 | C4 | D4 |
| | | | UMTS2->T × 1 | Y3 | Z3 | * | * |
| | | | UMTS2->T × 2 | Y3 | B1 | * | * |
| | | | UMTS2->UMTS1 | Y3 | X3 | * | * |
| AMPS RX | T × 2 | R × 1 | ANT->R × 1 | A1 | * | C1 | D1 |
| GSM RX | T × 2 | R × 2 | ANT->R × 2 | A1 | * | C2 | D2 |
| DCS RX | T × 1 | R × 3 | ANT->R × 3 | A1 | * | C3 | D3 |
| PCS RX | T × 1 | R × 4 | ANT->R × 4 | A1 | * | C4 | D4 |

The mode of SWM 500 shows the usage status of SWM 500. For instance, “AMPS/GSM TX” indicates AMPS or GSM transmission, and switch 550 at this time selects terminal Tx1, while switch 560 selects switch 550. That is, electricity is transmitted between terminal ANT and terminal Tx1. AMPS, GSM, DCS, PCS, UMTS800, UMTS1900, and UMTS2100 here represent wireless transmission systems. TX represents transmission and RX represents reception.

SWM 500 measures the transmission characteristics (for instance, S parameters S12 and S31) along each measurement path. For instance, judging from the measurement indicated in the top column, the mode of SWM 500 is “AMPS/GSM TX” and the measurement path is “Tx1->ANT.” Rows T1 through T4 clarify the internal connection status of test-set 200 when this measurement is executed. In this case, terminal T1 of test-set 200 is connected to terminal A1 and terminal T2 is connected to terminal Z3. It goes without saying that the signals under test are transmitted from terminal Z3 to terminal A1. The “*” under the columns for terminal T3 and T4 indicate that any connection may be used for terminal T3 and terminal T4. This asterisk is also entered in other rows (550) showing the selection status of switch 550, and it similarly means that switch 550 is selected as needed. Moreover, judging from the measurements represented in the second column, the mode of SWM 500 is “AMPS/GSM TX” and the measurement path is “TX1->Rx1.” Rx1 means the pair of terminals Rx1a and Rx1b; Rx2 means the pair of terminals Rx2a and Rx2b; Rx3 means the pair of terminals Rx3a and Rx3b; and Rx4 means the pair of terminals Rx4a and Rx4b. The measurement path is “TX1->Rx1;” therefore, transmission characteristics (signal leakage) are measured from terminal Tx1 to the pair of terminals Rx1a and Rx1b. In this case, terminal T2 is connected to terminal Z3 of test-set 200, terminal T3 is connected to terminal C1, and terminal T4 is connected to terminal D1.

Expanded script commands for measuring SWM 500 will now be described. The script commands that were previously described directly control switch 410, etc. individually. Two script commands “PORT2 B4” and “PORT7 Z2,” become necessary when electrically connecting terminal T2 to terminal Z3 in accordance with Table 1 using these script commands. This type of control method is complex and leads to program errors. Therefore, the script commands are expanded such that switches 410, 411, 412, 420, 430, 440, 450, 451, and 452 for connecting terminals together are regarded as one switch, as in FIG. 7, and each terminal of this imaginary switch can be designated. As a result, script command PORT1 designates X3, Y3, and Z3 as the new parameters (name of each connection destination terminal). The same expansion is performed for script command PORT2. The following are the parameters (connection destination terminal name) that can be designated by increased script commands PORT1 and PORT2.

PORT1: Either A1, A2, A3, A4, X3, Y3, or Z3

PORT2: Either B1, B2, B3, B4, X3, Y3, or Z3

For example, when terminals T1 and X3 are electrically connected, only the script command “PORT1 X3” should be entered and conducted. When control device 120 executes “PORT1 X3,” switch 410 selects terminal f, switch 411 selects terminal g, and switch 420 selects terminal f. When terminal A2 and terminal X1 are electrically connected as in FIG. 7, terminal T1 and terminal X3 are electrically connected. These additional parameters are effective for imaginary switches assuming a predetermined connection, but the related switches are controlled, regardless of whether or not there is a connection. The same is true for newly added parameters. As long as the newly added parameters are used, the user can designate the combination of terminals to be opened by the imaginary switch for the conduction of electricity. The real switches related to the imaginary switch control the selection status based on the designated combination. The real switch here means a switch that actually exists, specifically, switches 410, 411, 412, 420, 430, 440, 450, 451, 452, 460, 461, 462, 470, 471, and 472.

### WORKING EXAMPLE 2

The second embodiment of the present invention is the measurement of a 16-port filter bank. The four filters (510, 520, 530, and 540) inside SWM 500 are balanced-unbalanced filters; therefore, the number of ports of the filter bank with these filters is 12. However, 16 is the maximum number of ports of the filter bank when a filter bank is given as an individual product. Therefore, the present example describes the case where a 16-port filter bank serves as a device under test. FIG. 8 is a block diagram showing the internal structure of a 16-port filter bank. A filter bank 600 in FIG. 8 comprises balanced-unbalanced filters 610, 620, 630, and 640. Filter 610 comprises the balanced pair of terminals FL1a and FL1b, and the balanced pair of terminals FL1c and FL1d. Filter 620 comprises the balanced pair of terminals FL2a and FL2b and the balanced pair of terminals FL2c and FL2d. Filter 630 comprises the balanced pair of terminals FL3a and FL3b and the balanced pair of terminals FL3c and FL3d. Filter 640 comprises the balanced pair of terminals FL4a and FL4b and the balanced pair of terminals FL4c and FL4d.

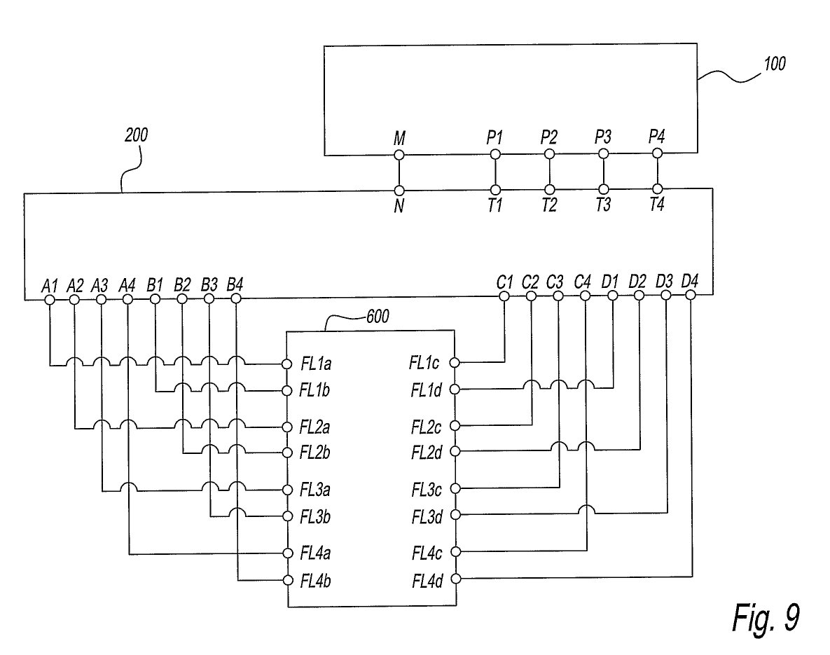

Refer to FIG. 9. FIG. 9 is a drawing showing the connection of network analyzer 100, test-set 200, and filter bank 600. The connection between network analyzer 100 and test-set 200 in FIG. 9 is the same as in FIG. 2 and a detailed description is therefore omitted. As shown in FIG. 9, terminal A1 is connected to terminal FL1a; terminal A2 is connected to terminal FL2a; terminal A3 is connected to terminal FL3a; terminal A4 is connected to terminal FL4a; terminal B1 is connected to terminal FL1b; terminal B2 is connected to terminal FL2b; terminal B3 is connected to terminal FL3b; and terminal B4 is connected to terminal FL4b. Moreover, terminal C1 is connected to terminal FL1c, terminal C2 is connected to terminal FL2c, terminal C3 is connected to terminal FL3c, terminal C4 is connected to terminal FL4c, terminal D1 is connected to terminal FL1d, terminal D2 is connected to terminal FL2d; terminal D3 is connected to terminal FL3d; and terminal D4 is connected to terminal FL4d. When measuring filter bank 600, there are no connections between the terminals of test-set 200.

Next, the measurement of each parameter of filter bank 600 will be described while referring to Table 2. Table 2 is a table showing the setting status of test-set 200 for measuring each parameter of filter bank 600. Moving from right to left from the furthest left column in FIG. 2 are the following: the column that shows the filter of filter bank 600 (filter) that is the subject of the measurement, the column that shows the internal connection destination of terminal T1 in test-set 200 (T1), the column that shows the internal connection destination of terminal T2 (T2), the column that shows the internal connection destination of terminal T3 (T3), and the column that shows the internal connection destination of terminal T4 (T4).

TABLE 2

Test-set

| Filter | T1 | T2 | T3 | T4 |
|---|---|---|---|---|
| 610 | A1 | B1 | C1 | D1 |
| 620 | A2 | B2 | C2 | D2 |
| 630 | A3 | B3 | C3 | D3 |
| 640 | A4 | B4 | C4 | D4 |

The transmission characteristics of each filter are measured. When filter 610 is measured, the transmission characteristics between the pair of terminals FL1a and FL1b and between the pair of terminals FL1c and FL1d are measured. When filter 620 is measured, the transmission characteristics between the pair of terminals FL2a and FL2b and the pair of terminals FL2c and FL2d are measured. When filter 630 is measured, the transmission characteristics between the pair of terminals FL3a and FL3b and the pair of terminals FL3c and FL3d are measured. When filter 640 is measured, the transmission characteristics between the pair of terminals FL4a and FL4b and the pair of terminals FL4c and FL4d are measured. For instance, terminal T1 is electrically connected to terminal A1, terminal T2 is electrically connected to terminal B1, terminal T3 is electrically connected to terminal C1, and terminal T4 is electrically connected to terminal D1 when the user sends the script commands “PORT1 A1,” “PORT2 B1,” “PORT3 C1,” and “PORT4 D1” to control device 120. As with the measurements of filter 610, the internal connections for test-set 200 are set in accordance with Table 2 for the measurement of filters 620, 630, and 640.

Measurement system 10 having the connections and structure shown in FIG. 9 is capable of measuring a filter bank regardless of whether the internal filters have a balanced-unbalanced or unbalanced-unbalanced structure.

Measurement system 10 described above can be modified. For instance, control part 110 and memory 120 can be replaced by a computer (not illustrated) that is externally connected to network analyzer 100 or test-set 200. In this case, the computer provides the programming environment for controlling the test-set and controls switches 410, etc. by executing the script commands provided by the user.

Moreover, test-set 200 can also newly comprise control terminals, which are not illustrated, in order to control switches 550 and 560 inside SWM 500. In such a case, a control line represented by the broken arrows in FIG. 6 most likely will be connected between test-set 200 and SWM 500.

Furthermore, by means of the above-mentioned second embodiment, the selection terminals of a single-pole, two-throw switch are connected to the selection terminals of a single-pole, four-throw switch, but the common terminal of the single-pole, two-throw switch can also be connected to the selection terminal of the single-pole, four-throw switch. Test-set 200 connected in this way, for instance, is applied to SWM 500 when the number of antenna terminals has been increased to two or more in order to respond to diversity. For instance, when the number of ANT terminals of SWM 500 have been increased to two, the system is changed such that terminal A1 in connected test set 200 shown in FIG. 7 is connected to terminal X3 and terminal B2 is connected to terminal UMTS1, and terminals X1 and X2 are connected to the respective antenna terminals.

1. A test-set for connecting a device under test having more terminals than the number of measurement ports in a network analyzer to said network analyzer, said test-set comprising multiple one-pole, multi-throw switches that will be electrically connected to said measurement ports and at least one switch capable of being connected as needed to a selection terminal of said one-pole, multi-throw switch in a same chassis.

2. The test-set according to claim 1, wherein said network analyzer is a 4-port network analyzer which comprises 4 one-pole, four-throw switches and 3 one-pole, two-throw switches, and a selection terminal of said one-pole two-throw switches is capable of being connected as needed to a selection terminal of said one-pole four-throw switches.

3. A system for measuring a multiport device connected to a network analyzer via a test-set; a test-set having multiple real switches wherein at least one set of said real switches is capable of being connected together as needed between terminals; and a device for controlling said network analyzer and said test-set, two or more of said real switches that have been connected together with predetermined connection are regarded as one imaginary switch, and said control device controls the selection status of said real switches related to said imaginary switch based on the combination of terminals to be conducted each other as instructed by the user for said imaginary switch.

4. A system according to claim 3; wherein at least one set of said real switches is capable of being connected together as needed between selection terminals.

5. A system according to claim 3; wherein said real switches regarded as one imaginary switch includes at least one real switch which at least one selection terminal is connected to at least one selection terminal of the other at least one real switch.
